(19) United States
(12) Patent Application Publication
(10) Pub. No.: US 2018/0331079 A1
(43) Pub. Date: Nov. 15, 2018

(54) WATERPROOF SEALED CIRCUIT APPARATUS AND METHOD OF MAKING THE SAME

(71) Applicant: Rohinni, LLC, Coeur d' Alene, ID (US)

(72) Inventors: Justin Wendt, Post Falls, ID (US); Andy Huska, Liberty Lake, WA (US); Sean Kupcow, Greenacres, WA (US); Nicholas Steven Busch, Spokane, WA (US); Cody Peterson, Hayden, ID (US)

(21) Appl. No.: 15/593,230

(22) Filed: May 11, 2017

(51) Int. Cl. H01L 25/075; H05K 1/18; H05K 1/02; H05K 3/28; H01L 33/62; H01L 33/56

(52) U.S. Cl. CPC H01L 25/0753; H05K 1/181; H05K 1/028; H05K 3/284; H01L 33/62; H05K 2203/166; H05K 2201/10522; H05K 2201/10106; H05K 2203/1316; H01L 2933/005; H01L 33/56

(57) ABSTRACT

A waterproof sealed circuit apparatus includes a circuit substrate having a first side opposite a second side. The first side includes a circuit trace. A semiconductor device die is electrically coupled to the circuit trace on the first side of the circuit substrate. A polymer sealing layer is adhered to the first side of the circuit substrate and covers the semiconductor device die. Polymer chains of the sealing layer are crosslinked.

### CROSS REFERENCE TO RELATED PATENT APPLICATIONS

This application incorporates U.S. Pat. No. 9,502,625, filed on Jun. 3, 2015, entitled “Electrophotographic Deposition of Unpackaged Semiconductor Device;” U.S. patent application Ser. No. 14/939,896, filed on Nov. 12, 2015, entitled “Method and Apparatus for Transfer of Semiconductor Devices;” U.S. patent application Ser. No. 15/343,055, filed on Nov. 3, 2016, entitled “Compliant Needle for Direct Transfer of Semiconductor Devices;” U.S. patent application Ser. No. 15/360,645, filed on Nov. 23, 2016, entitled “Pattern Array Direct Transfer Apparatus and Method Therefor;” U.S. patent application Ser. No. 15/360,471, filed on Nov. 23, 2016, entitled “Top-Side Laser for Direct Transfer of Semiconductor Devices;” and U.S. patent application Ser. No. 15/409,409, filed on Jan. 18, 2017, entitled “Flexible Support Substrate for Transfer of Semiconductor Devices;” in their entireties by reference.

### BACKGROUND

Generally, for the large majority of electronic devices, moisture is harmful to the functionality of the electronic circuits in such devices. For some devices, waterproof enclosures have been designed and may have “shell-like” structures that are placed around the outside of the devices. These shell structures often clamp or otherwise seal around the entire device. In other devices, the outer housing of the device itself has been designed as a sealed enclosure to seal out moisture intrusion. However, enclosures that clamp around a device are waterproof tend to be bulky and are often rigid due to the fragility of the device components and electronic circuits. Likewise, enclosures that are the outer housing of the device are also generally rigid. While the seals on such devices are often well-tested and intended to be durable, if a seal on the case of the enclosure (or housing) happens to fail, the electronic circuits within the device are likely to be irreparably damaged.

The functions and components of the circuits of these electronic devices vary widely depending on the desired features. An example of a component that may be used on a device designed to be waterproof is a semiconductor device. Semiconductor devices are typically manufactured as single discrete devices or as integrated circuits (ICs). Examples of single discrete devices include electrically-actuatable elements such as light-emitting diodes (LEDs), diodes, transistors, resistors, capacitors, fuses, and the like.

The fabrication of semiconductor devices typically involves an intricate manufacturing process with a myriad of steps. The conventional end-product of the fabrication is a “packaged” semiconductor device. The “packaged” modifier refers to the enclosure and protective features built into the final device as well as the interface that enables the device in the package to be incorporated into a circuit.

The conventional fabrication process for semiconductor devices starts with handling a semiconductor wafer. The wafer is diced into a multitude of “unpackaged” semiconductor devices. The “unpackaged” modifier refers to an unenclosed semiconductor device without protective features. Herein, unpackaged semiconductor devices may be called semiconductor device dies, or just “dies” for simplicity. A single semiconductor wafer may be diced to create dies of various sizes, so as to form upwards of more than 100,000 or even 1,000,000 dies from the semiconductor wafer (depending on the starting size of the semiconductor). Usually, the unpackaged dies are then “packaged” via a conventional fabrication process.

Packaged or unpackaged, semiconductor device dies are vulnerable to damage from moisture. Thus, prevention of moisture access to circuits is important. However, due to the nature of the components used in some circuits, another sometimes important aspect may be visibility of the component, such as, for example, when the semiconductor device dies is an LED from which emitted light is intended to be visible to a user. Thus, in some instances, at least with respect to LEDs, an enclosure may hinder the ability to see the emitted light. Furthermore, an enclosure is not always desirable, as the additional housing adds bulk and volume to a circuit that might otherwise be able to be placed in a particularly small space or in a place or position that does not interfere with other elements involved in an apparatus or use thereof.

Notably, the LED industry provides a lighting means that consumes less energy and is more physically robust, smaller, faster-switching, and longer lasting than previous lighting elements. However, the size, functionality, and configuration of conventional LEDs have constrained the use of LEDs to particular applications. For example, as the size of an LED in a circuit decreases, the size of the circuit trace that powers the LED decreases as well. Under such size constraints, the strength and durability of the circuits also decrease, thus rendering a product implementing the circuit more susceptible to breaking under smaller forces. On the other hand, an increase in the strength or durability of the circuit and/or circuit trace may increase rigidity of a circuit due to an increase in thickness or type of material used. As such, such a circuit may be limited in application.

### BRIEF DESCRIPTION OF THE DRAWINGS

The Detailed Description is set forth with reference to the accompanying figures. In the figures, the left-most digit(s) of a reference number identifies the figure in which the reference number first appears. The use of the same reference numbers in different figures indicates similar or identical items. Furthermore, the drawings may be considered as providing an approximate depiction of the relative sizes of the individual components within individual figures. However, the drawings are not to scale, and the relative sizes of the individual components, both within individual figures and between the different figures, may vary from what is depicted. In particular, some of the figures may depict components as a certain size or shape, while other figures may depict the same components on a larger scale or differently shaped for the sake of clarity.

FIG. 1A illustrates a top view of a waterproof sealed circuit apparatus according to an embodiment of the instant application.

FIG. 1B illustrates a cross-sectional side view of an embodiment of the waterproof sealed circuit apparatus according to FIG. 1A.

FIG. 1C illustrates a cross-sectional side view of another embodiment of the waterproof sealed circuit apparatus according to FIG. 1A.

FIG. 2 illustrates a side view of an embodiment of a layered stack to form a waterproof sealed circuit apparatus according to the instant application.

FIG. 3 illustrates a method of forming a waterproof sealed circuit apparatus according to an embodiment of the instant application.

FIG. 4 illustrates additional potential steps of the method of forming a waterproof sealed circuit apparatus according to FIG. 3.

FIG. 5 illustrates additional potential steps of the method of forming a waterproof sealed circuit apparatus according to FIG. 3.

### DETAILED DESCRIPTION

### Overview

This disclosure is directed to a sealed circuit apparatus. More specifically, the disclosure and figures herewith describe a circuit apparatus that is sealed against moisture and chemical disturbance such that the circuit elements of a circuit substrate may be protected from damage caused by water moisture and/or other chemical elements harmful to electronic circuits. Furthermore, the sealed circuit disclosed herein retains extreme flexing capabilities after the sealing layer is formed without causing damage to the circuit functionality. The instant application further describes details of a method for forming the sealed circuit apparatus.

Moreover, the waterproofing techniques and embodiments for sealed circuits discussed herein are well-suited for circuits formed according to embodiments and methods described in U.S. patent application Ser. No. 14/939,896. Further, the techniques and embodiments herein are also suitable for circuits formed using conventional methods as well.

That is, the techniques of the instant application are effective with circuits created via methods discussed in the reference listed above, which frequently use micro-sized LEDs, and the techniques of the instant application are effective for circuits created via other methods not discussed, which may use micro-sized LEDs or conventional LEDs. For the purposes of this application, a micro-sized LED may be considered to include, but not be limited to, semiconductor device die, such as for example unpackaged LED die that are extremely small and thin. For example, the thickness of an unpackaged die (e.g., height that a die extends above a surface) may range from about 12 microns to about 400 microns, or from about 12 to about 200 microns, or from about 25 to about 100 microns, or from about 50 to about 80 microns. A lateral dimension of a die may range from about 20 microns to about 800 microns. Due to the small size of the dies relative to the size of the circuit substrate, the challenge of precisely aligning and placing the dies may be alleviated by using a machine such as those discussed in any of U.S. Pat. No. 9,502,625, U.S. patent application Ser. No. 14/939,896, U.S. patent application Ser. No. 15/343,055, U.S. patent application Ser. No. 15/360,645, U.S. patent application Ser. No. 15/360,471, and/or U.S. patent application Ser. No. 15/409,409.

### Illustrative Embodiments of a Waterproof Sealed Circuit Apparatus

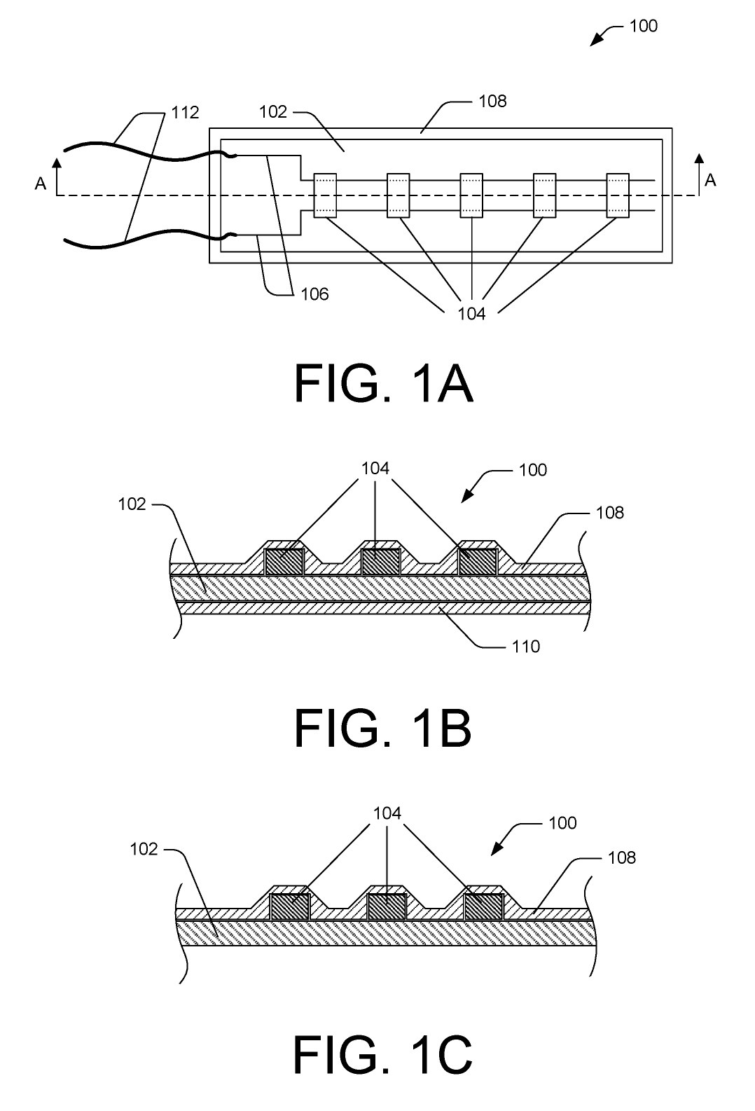

Specifically, FIG. 1A depicts a top view of a waterproof sealed circuit apparatus 100 according to an embodiment described herein. Inasmuch as some reference numbers in FIG. 1A are implemented in FIGS. 1B and 1C, additional aspects of apparatus 100 are discussed with respect to FIGS. 1B and 1C. Notably, FIGS. 1B and 1C depict cross-sectional views of alternative embodiments of FIG. 1A taken at line A-A. That is, in an embodiment, apparatus 100 may have a cross-section that appears like that depicted in FIG. 1B. Alternatively, in a different embodiment, apparatus 100 may have a cross-section that appears like that depicted in FIG. 1C. One or more differences between the alternative cross-sectional views is described further herein.

Apparatus 100 may include a circuit substrate 102 and one or more semiconductor device die 104. FIG. 1A depicts five semiconductor device die 104, however, a circuit substrate may contain fewer or more than five. In use, semiconductor device die 104 may be electrically connected to a power source (not depicted) via one or more circuit trace lines 106. Further, circuit trace 106 lines may be fixed in place on circuit substrate 102. As such, circuit trace lines 106 may facilitate securing semiconductor device die 104 to circuit substrate 102.

In an embodiment, the waterproofing and chemical intrusion preventing feature of apparatus 100 may be achieved via a polymer sealing layer 108, which may extend beyond a perimeter edge of circuit substrate 102, as depicted. Note, sealing layer 108 may be a first sealing layer 108 disposed on a first side of circuit substrate 102 to cover semiconductor device die 104; and, as depicted in FIG. 1B, a second polymer sealing layer 110 may be disposed on a second side of circuit substrate 102 to cover the back side thereof. Note, second polymer sealing layer 110 may or may not be the same material as the material of first sealing layer 108.

Additionally, and/or alternatively, sealing layer 108 may be a top side sealing layer where desired, and may seal directly against circuit substrate 102. In such an embodiment, circuit substrate 102 may be formed of a material that bonds well with sealing layer 102. In an embodiment, circuit substrate 102 may be formed of the same material as is used for sealing layer 108.

In an embodiment, sealing layer 108 and sealing layer 110 may include ethylene-vinyl acetate (“EVA”). Additionally, the EVA may include a material that has properties of an adhesion promoter, and a material that has properties of a UV light inhibitor. Alternatively, sealing layer 108 and sealing layer 110 may include other suitable materials that provide similar properties as EVA. For example, some desirable properties in other suitable materials may include waterproofing characteristics, maintaining a flexible structural composition after melting and reforming, and providing chemical intrusion resistance to the circuit substrate and components thereon. Furthermore, sealing layer(s) may be used to bond circuit substrate 102 to additional layers (not shown) of a circuit stack up.

As depicted in FIG. 1A, apparatus 100 may further include electrically conductive leads 112 that connect to and extend from circuit trace lines 106. Apparatus 100 may be powered by an external power source (not shown) via leads 112. In an embodiment, a portion of leads 112 may be sealed with the circuit, as shown, from a point of contact with circuit trace lines 106 to an edge of sealing layer 108. Additionally, and/or alternatively, leads 112 may be completely sealed by sealing layer 108 (or sealing layer 108 and second sealing layer 108) (not shown). In a case where leads 112 are completely sealed, power may be supplied to apparatus 100 by using a crimp-on styled connector (e.g., vampire connector) to bite into the sealing layer 108/110 until contact is made with leads 112 and thereby provide an electrical connection to leads 112.

Another characteristic of apparatus 100 relates to the level of flexibility of apparatus 100. Specifically, the flexibility of apparatus 100 may be determined, at least in part, by the bend radius thereof. For the purposes of this application, the bend radius is defined as the minimum radius that the apparatus can bend without kinking (i.e., creating an acute angle at a fold line between portions of the apparatus as a first part is bent toward a second continuous part of the same apparatus) or damaging the circuit therein (e.g., breaking circuit connections or components such that the circuit or a part thereof fails; or disrupting the sealing layer such that it fails to protect the circuit inside from water or chemical intrusion). In an embodiment, apparatus 100 may have a bend radius ranging from about 0.5 mm to about 30 mm, or from about 0.75 mm to about 20 mm, or from about 1 mm to about 15 mm, or from about 1.5 mm to about 5 mm. Note that the bend radius may depend, at least in part, on one or more of the following factors: the respective thicknesses of sealing layer/s 108/110, circuit trace 106, and circuit substrate 102; the hardness of the material used for the circuit substrate 102; and the size of, number of, and spacing between semiconductor device die 104 attached to the circuit substrate 102. Accordingly, in an example embodiment, where waterproofing and rigidity are desired, a circuit apparatus may implement a rigid material for the circuit substrate, while implementing EVA (discussed above) as the sealing layer(s). Alternatively, a thin, flexible circuit apparatus may be desired, wherein a thin, flexible layer of material may be chosen for the circuit apparatus and EVA may be implemented as the sealing layer(s).

Furthermore, inasmuch as apparatus 100 has a negligible water permeability rate, apparatus 100 may be considered substantially waterproof. As such, apparatus 100 may be used in many environments without concern for moisture damaging apparatus 100. Apparatus 100 may also be substantially unaffected by freezing temperatures.

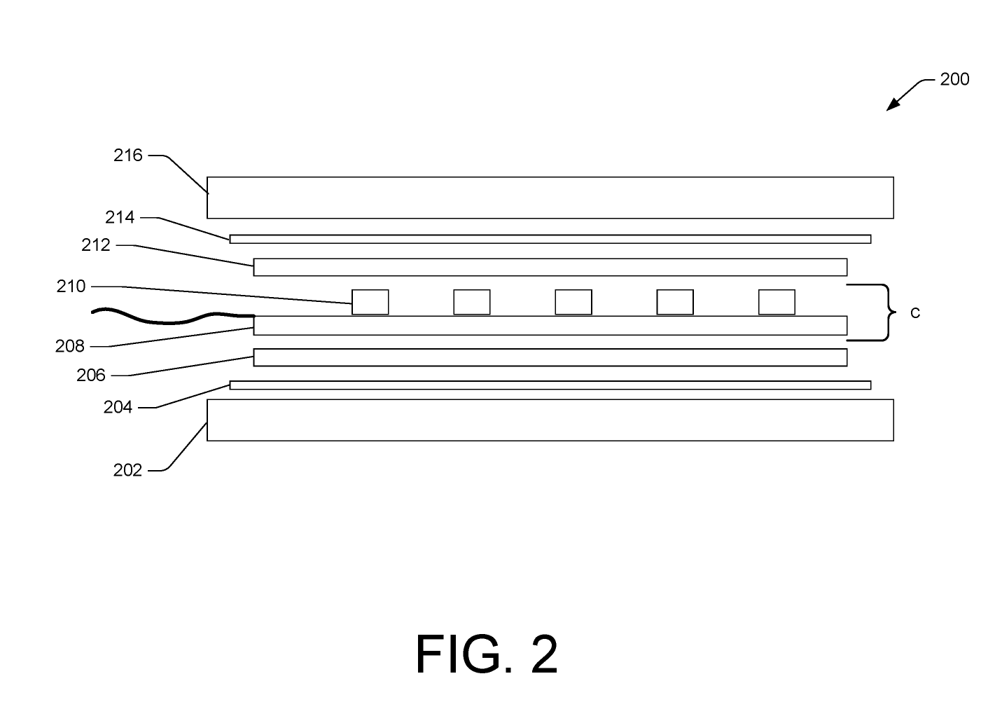

In FIG. 2, an embodiment of a layered stack 200 including potential layers of materials that may be involved in forming a sealed circuit is depicted. In forming a sealed circuit, according to the instant application, various different materials may be organized in a layered order before performing additional actions with the materials, via which the circuit electronics may become sealed. Note, it is contemplated that other means of producing a sealed circuit may be possible, in which fewer or more layers are involved in the process. As such, while each depicted layer in layered stack 200 is described herein below to provide an example embodiment, other processes or methods may exist in which fewer material layers are used or in which more material layers are used.

Further to the above discussion, layered stack 200 may include a base layer 202 that acts as a support on which a sealed apparatus may be formed. Layered stack 200 may further include a first release liner layer 204, which may be released from one or both of base layer 202 and/or a first sealing layer 206 subsequent to formation of the sealed apparatus. A circuit substrate 208 forms the foundation of the electrically conductive circuit C in the sealed apparatus, and may be placed directly on first sealing layer 206 in layered stack 200. Circuit substrate 208 may further have deposited thereon one or more electrically-actuatable elements 210 (e.g., LEDs, micro-LEDs, resistors, capacitors, semiconductor components, etc.) that are powerable via leads 112 and circuit trace lines 106 (as seen in FIG. 1). A second sealing layer 212 may be placed on top of the electrically conductive circuit C to seal and protect the circuitry of the sealed circuit apparatus. As depicted in FIG. 2, above the second sealing layer 212, a second release liner layer 214 may be added, which may be released from one or both of second sealing layer 212 and/or an upper layer 216. Upper layer 216 may act as a weighted surface that is placed above the second sealing layer 212 to pull upper layer 216, under vacuum pressure or gravity, against second sealing layer 212, thereby assisting in spreading second sealing layer 212 and/or first sealing layer 206, when softened, evenly across the top and/or bottom surfaces of the electrically conductive circuit C.

Base 202 may be a layer of material including one or more of: metal (e.g., aluminum, steel, etc.), glass, plastic (e.g., polyetheretherketone (PEEK), kapton, polyphenylene sulfide (PPS), polyetherimide (PEI), etc.), stone, ceramic, etc. Additionally, base 202 may be formed of a rigid or a non-rigid material, and may have a melting point above a melting point of first sealing layer 206 and/or second sealing layer 212. For example, in an embodiment where the melting point of first sealing layer 206 and/or second sealing layer 212 ranges between 160° C. and the melting point of 180° C., the melting point of base 202 may be above about 180° C.

As stated above, a sealed circuit apparatus may be formed with fewer or more layers than described herein. For example, in an embodiment, one or more of first release liner layer 204, first sealing layer 206, second release liner layer 214, or upper layer 216 may not be included in the formation of the sealed circuit apparatus. Regardless, when applied, one or both of first release liner layer 204 or second release liner layer 214 may be formed of a material that does not bind with the sealed circuit apparatus during the formation thereof. That is, during the formation process of the sealed circuit apparatus, as described in more detail below, when applied, first release liner layer 204 does not form a molecular level bond with either the first substrate 202 or first sealing layer 206 with which contact occurs. Likewise, when applied, second release liner layer 214 does not form a molecular level bond with either the second sealing layer 212 or upper layer 216 with which contact occurs. Regarding the description that no “molecular level bond” occurs, this indicates that, despite any deformation or change of phase that may occur with the material of first release liner layer 204 and/or second release liner layer 214 during the process of forming the sealed circuit apparatus, first release liner layer 204 and/or second release liner layer 214 may be releasable from the adjacent layers in layered stack 200 after formation. Therefore, first release liner layer 204 and second release liner layer 214 may include materials that are not compatible with bonding integrally with the materials of the adjacent layers. Such materials may include, but are not limited to: ceramics, polymers, paper, etc. In an example embodiment, a release liner layer may include a combination of materials, such as a polyester having a silicone-based release coating.

First sealing layer 206 and second sealing layer 212, as discussed above may provide waterproofing and chemical intrusion properties to protect electrically conductive circuit C. The material of first sealing layer 206 and second sealing layer 212 need not be the same, although it may be the same. As mentioned previously, an example material may include EVA, and may further include a material additive that has properties of an adhesion promoter, and a material additive that has properties of a UV light inhibitor. In another embodiment, the material of the sealing layer(s) may include PVB having similar additives as described above. Additionally, the phase of the material of the sealing layer(s) may vary from liquid to solid (e.g., a liquid form that is pourable to a thin sheet).

The material of circuit substrate 208 may vary depending on desired purposes. For example, circuit substrate 208 may be rigid or flexible. In an embodiment, circuit substrate 208 may be formed of a same material as second sealing layer 212, in which case, first sealing layer 206 may be unnecessary, as circuit substrate 208 may seal directly with second sealing layer 212.

With regard to upper layer 216, when implemented, a material thereof may be selected to provide heat conductivity to the rest of layered stack 200, as well as weighted pressure to assist in compressing and spreading second sealing layer 212 over electrically conductive circuit C. Additionally, upper layer 216 may be formed of a non-porous material to prevent “printing” of second sealing layer 212. Under vacuum the material of the sealing layer(s) may liquefy and become molded to whatever element is placed vertically adjacent. While this may be a desired effect for diffusion or bonding purposes in some instances, this effect may impact optical clarity. Thus, in an embodiment, the material of upper layer 216 may include glass. A glass pane layer as the upper layer 216 may be about ¼ inch thick and may be a material with low-iron content to minimize the potential effects of thermal processing on the material.

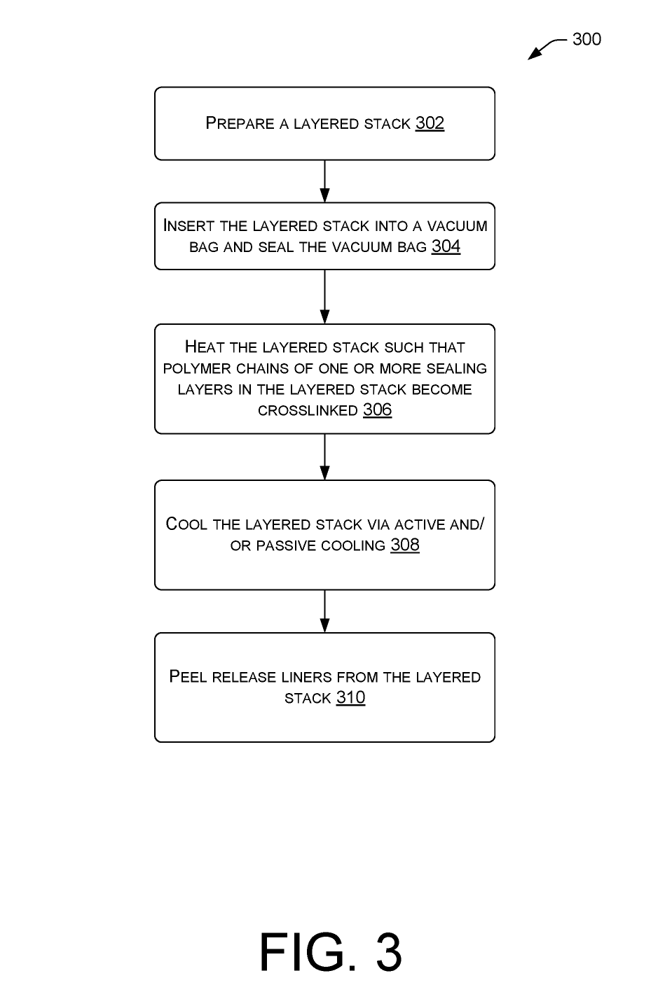

FIG. 3 depict an embodiment of a flow schematic of a method 300 of making a sealed circuit apparatus. Step 302 of method 300 includes preparing a layered stack. In step 304, the layered stack may be inserted into a vacuum bag and then the vacuum bag may be sealed. The layered stack is heated in step 306 such that the polymer chains of one or more sealing layers in the layered stack become crosslinked. Crosslinking in the sealing layer(s) material provides a unique bond of the particles to seal the polymer around the circuitry and strengthen the polymer and provide waterproofing and chemical resistance properties, while also enabling flexibility without breaking.

After heating the layered stack in step 306, the layered stack may be cooled in step 308, via active and/or passive cooling. In active cooling, an active action of deliberate cooling of the layered stack may be taken, such as placing the layered stack in the path of directed air created by a fan or air conditioning function or device. The cooling of the layered stack removes heat from the layered stack to allow the stack to be better handled and manually remove remaining layers that are not to form a part of the sealed circuit apparatus. Furthermore, the layered stack may alternatively, and/or additionally, be cooled passively by allowing the stack to cool in the ambient air. The amount of time to cool may range from about 30 seconds to about 2 minutes, or may be less than 30 seconds or greater than 2 minutes.

Method 300 may further include step 310 of peeling the release liners from the sealed circuit apparatus in the layered stack after removing the layered stack from the vacuum bag. At this point, the sealed circuit apparatus may be implemented in a device for use or may be used as is.

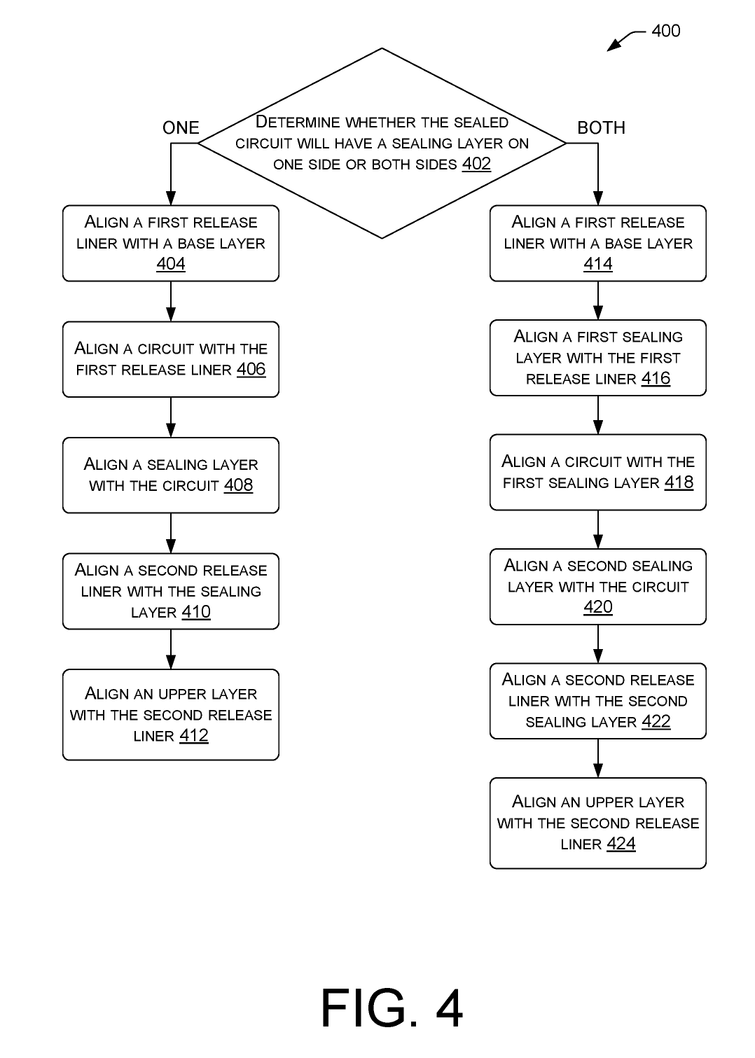

As indicated above, prior to heating the layered stack, the layered stack is prepared. As part of this preparation, a determination may be made regarding the configuration of the sealed circuit apparatus. Thus, in FIG. 4, an embodiment of a method 400 of preparing the layered stack is depicted. In particular, method 400 may include a step 402 of determining whether the sealed circuit apparatus will have a sealing layer on one side or both sides of the electrically conductive circuit (“circuit”). Upon a determination that only one side of the circuit will have a sealing layer, a step 404 may occur in which a first release liner may be aligned with a base layer to start the layered stack. In step 406, the circuit may be aligned with the first release liner. A sealing layer may be aligned with the circuit in step 408, and a second release liner may be aligned with the sealing layer in step 410. At the top of the stack, an upper layer may be aligned with the second release liner at step 412.

Alternatively, upon a determination that both sides of the circuit will have a sealing layer, a step 414 may occur in which a first release liner may be aligned with a base layer to start the layered stack. In step 416, a first sealing layer may be aligned with the first release liner. Further, in step 418, the circuit may be aligned with the first sealing layer. A second sealing layer may be aligned with the circuit in step 420, and a second release liner may be aligned with the second sealing layer in step 422. At the top of the stack, an upper layer may be aligned with the second release liner at step 424. It is contemplated that additional or fewer steps may be implemented in the preparation of the layered stack. For example, edges of the formed sealed circuit apparatus may be trimmed to provide greater aesthetics or to adjust the size.

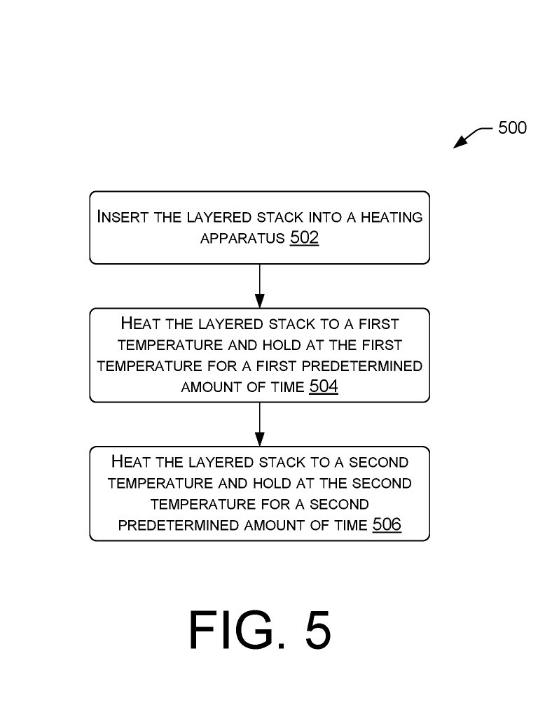

As discussed above, the layered stack may be heated to assist in forming the sealed circuit apparatus. FIG. 5 depicts additional steps in a method 500 that may occur as part of heating the layered stack. Specifically, step 502 may include inserting the layered stack into a heating apparatus, such as for example, an oven, and the layered stack may further be under a vacuum environment. The oven may be a multi-stage oven in which steps 504 and 506 may be effectuated. That is, in step 504, the layered stack may be heated to a first temperature and held at the first temperature for a first predetermined amount of time. Then, in step 506, the layered stack may be heated to a second temperature and held at the second temperature for a second predetermined amount of time. In an embodiment, the second temperature may be greater than the first temperature. For example, the first temperature may range from about 70° C. to about 90° C., or from about 75° C. to about 85° C., or from about 80° C. to about 85° C. Further, the second temperature may range from about 100° C. to about 160° C., or about 110° C. to about 155° C., or about 120° C. to about 145° C., or from about 130° C. to about 145° C. In an embodiment, the second temperature may be about 100° C. or greater.

The respective durations of the first predetermined amount of time and the second predetermined amount of time may depend, at least in part, on the desired thickness of the sealed circuit apparatus. Further, less time may be needed as the quality of the vacuum environment increases. Additionally, and/or alternatively, downward pressure on the layered stack may assist in removing air from in between the layers of the layered stack. A heated platen press and/or spring-tensioned heated rollers may be implemented to assist in removing the air. In an embodiment, the first predetermined amount of time may range from about 1 minute to about 10 minutes, or from about 2 minutes to about 8 minutes, or from about 3 minutes to about 5 minutes. Moreover, in an embodiment, the second predetermined amount of time may range from about 5 minutes to about 20 minutes, or from about 7 minutes to about 15 minutes, or from about 9 minutes to about 10 minutes.

### CONCLUSION

Although several embodiments have been described in language specific to structural features and/or methodological acts, it is to be understood that the claims are not necessarily limited to the specific features or acts described. Rather, the specific features and acts are disclosed as illustrative forms of implementing the claimed subject matter.

What is claimed is:

1. A waterproof sealed circuit apparatus, comprising:
a circuit substrate having a first side opposite a second side, the first side including a circuit trace;
a semiconductor device die electrically coupled to the circuit trace on the first side of the circuit substrate; and
a polymer sealing layer adhered to the first side of the circuit substrate and covering the semiconductor device die, and polymer chains of the sealing layer being crosslinked.

2. The apparatus according to claim 1, wherein a thickness of the apparatus is less than or equal to about 1 mm.

3. The apparatus according to claim 1, wherein the circuit substrate is a strip including a plurality of semiconductor device die dispersed along a length of the strip, the plurality of semiconductor device die being spaced apart by a distance ranging from about 1 mm to about 10 mm.

4. The apparatus according to claim 1, wherein the sealing layer extends beyond an edge of the circuit substrate and is molded to the circuit substrate.

5. The apparatus according to claim 1, wherein at least a portion of the sealing layer is translucent.

6. The apparatus according to claim 1, wherein the semiconductor device die is an LED.

7. The apparatus according to claim 6, wherein the LED is a micro-sized LED having a height ranging from about 12 microns to about 400 microns.

8. The apparatus according to claim 1, wherein the apparatus is flexible, having a bend radius ranging from about 1 mm to about 15 mm.

9. The apparatus according to claim 1, wherein the sealing layer includes ethylene vinyl acetate (“EVA”).

10. A sealed circuit apparatus, comprising:
a circuit substrate having attached thereto at least one LED, the circuit substrate formed of a flexible film; and
a sealing sheet molded on the circuit substrate and the at least one LED, a material of the sealing sheet being a polymer, and polymer chains of the sealing sheet being crosslinked.

11. The apparatus according to claim 10, wherein the circuit substrate includes a same material as a material of the sealing sheet.

12. The apparatus according to claim 10, further comprising electrical leads that extend beyond a perimeter of the sealing sheet, the electrical leads configured to provide power to the at least one LED.

13. The apparatus according to claim 10, wherein a melt temperature of the circuit substrate is higher than a melt temperature of the sealing sheet.

14. The apparatus according to claim 10, wherein the sealing sheet is a first sealing sheet, and
wherein the apparatus further comprises a second sealing sheet molded onto a back side of the circuit substrate.

15. A method of forming a waterproof sealed circuit apparatus, the method comprising:
preparing a layered stack, including:
aligning a first release liner with a rigid substrate,
aligning a circuit substrate with the first release liner, the circuit substrate having attached thereto at least one LED,
aligning a sealing layer with the circuit substrate, and
aligning a second release liner with the sealing layer; and
heating the layered stack such that the sealing layer adheres to the circuit substrate and polymer chains of the sealing layer become crosslinked.

16. The method according to claim 15, wherein the sealing layer is a first sealing layer, and
wherein the preparing further includes aligning a second sealing layer with the first release liner prior to the aligning the circuit substrate with the first release liner.

17. The method according to claim 16, wherein a material of the first sealing layer and the second sealing layer includes ethylene vinyl acetate (“EVA”).

18. The method according to claim 15, wherein the heating includes:
heating the layered stack to a first temperature and holding thereat for a first predetermined amount of time, and
heating the layered stack to a second temperature for a second predetermined amount of time, the second temperature being greater than the first temperature.

19. The method according to claim 18, wherein the first temperature ranges from about 70° C. to about 90° C., and the second temperature ranges from about 100° C. to about 160° C.

20. The method according to claim 15, further comprising cooling the layered stack via ambient air after the heating.
